(19) United States
(12) Patent Application Publication
(10) Pub. No.: US 2009/0152102 A1
(43) Pub. Date: Jun. 18, 2009

(54) TRANSPARENT OPTICAL FILM AND METHOD OF FORMING THE SAME

(75) Inventors: Mikihiro Takemoto, Tokyo (JP); Toshitaka Kawashima, Kanagawa (JP); Yoshihiro Oshima, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/330,225

(22) Filed: Dec. 8, 2008

(30) Foreign Application Priority Data
Dec. 14, 2007 (JP) 2007-323054

(51) Int. Cl. C23C 14/34

(52) U.S. Cl. 204/192.15

(57) ABSTRACT

A method of forming a transparent optical film includes the step of forming an optical film that is transparent on a substrate by a reactive sputtering process using a Mg—Si metal target in an atmosphere into which a gas of a fluorine-containing compound is introduced and in which the total pressure is adjusted to 8 Pa or more.

### CROSS REFERENCES TO RELATED APPLICATIONS

The present invention contains subject matter related to Japanese Patent Application JP 2007-323054 filed in the Japanese Patent Office on Dec. 14, 2007, the entire contents of which are incorporated herein by reference.

### BACKGROUND OF THE INVENTION

1. Field of the Invention

The present invention relates to a transparent optical film with low refractive index and a method of forming the same.

2. Description of the Related Art

In display devices, such as cathode-ray tubes (CRTs) and liquid crystal displays, an antireflection film is generally disposed on the image display surface. The antireflection film is provided in order to alleviate the glare of external light so that good images and character information can be reproduced, and is formed by stacking thin films having different refractive indices.

Such an antireflection film, for example, has a structure in which a low-refractive-index optical film composed of a low-refractive-index material, such as silicon oxide, silicon nitride, or magnesium fluoride, and a high-refractive-index optical film composed of a high-refractive-index material, such as ITO (tin oxide-containing indium oxide), titanium oxide, tantalum oxide, or zirconium oxide, are stacked on a transparent film base composed of an organic material.

With respect to low-refractive-index optical films, Japanese Unexamined Patent Application Publication No. 7-166344 (Patent Document 1) discloses a method of forming a MgF₂ thin film by DC sputtering using a Mg target. In the method, deposition is performed in an atmosphere of Ar+CF₄, Ar+CF₄+O₂, or the like, in which the total pressure is set at about 0.4 Pa. However, Patent Document 1 does not describe the extinction coefficient. When the present inventors carried out the same experiments, it was not possible to form a MgF₂ thin film in which no absorption occurred. That is, although it was possible to form a low-refractive-index thin film, the resulting film was an absorptive film, and transmittance appropriate for an optical film was not obtained.

Furthermore, Japanese Unexamined Patent Application Publication No. 8-134637 (Patent Document 2) discloses a method of forming a low-refractive-index thin film with low light absorption. Patent Document 2 proposes the formation of a thin film with low light absorption using a MgFxOy target. However, since the target is an insulator, discharging is limited to RF discharging, and the deposition rate is insufficient, all of which are problems.

### SUMMARY OF THE INVENTION

It is desirable to provide a method of forming a transparent optical film in which a transparent, low-refractive-index optical film can be formed at a high deposition rate, and to provide a transparent optical film formed by the method.

According to an embodiment of the present invention, there is provided a method of forming a transparent optical film, the method including the step of forming an optical film that is transparent on a substrate by a reactive sputtering process using a Mg—Si metal target in an atmosphere into which a gas of a fluorine-containing compound is introduced and in which the total pressure is adjusted to 8 Pa or more. In the method, preferably, the Si content in the Mg—Si metal target is 50 mole percent or less. Furthermore, the fluorine-containing compound is preferably CF₄ or C₂F₆. Furthermore, in the reactive sputtering process, preferably, an alternating current voltage or a direct current voltage is applied between the substrate and the target.

According to another embodiment of the present invention, there is provided a transparent optical film formed on a substrate by a reactive sputtering process using a Mg—Si metal target in an atmosphere into which a gas of a fluorine-containing compound is introduced and in which the total pressure is adjusted to 8 Pa or more.

In the method of forming a transparent optical film according to the embodiment of the present invention, it is possible to form, at a high deposition rate, a low-refractive-index optical film in which no light absorption occurs in the visible region. Furthermore, the transparent optical film according to the embodiment of the present invention can be used as an optical thin film, such as an antireflection film.

### BRIEF DESCRIPTION OF THE DRAWINGS

FIG. 1 is a schematic diagram showing a structure of a reactive sputtering apparatus used in an embodiment of the present invention;

FIG. 2 is a graph showing the results of measurement of transmittance of samples and a glass substrate in Experimental Example 1;

FIG. 3 is a graph showing the influence of gas species on the deposition rate in reactive sputtering;

FIG. 4 is a graph showing the results of measurement of transmittance of samples in Experimental Example 2;

FIG. 5 is a graph showing the relationship between the CF₄/Ar flow ratio and the average transmittance;

FIG. 6 is a graph showing the relationship between the total pressure and the deposition rate during deposition in Experimental Example 3;

FIG. 7 is a graph showing the relationship between the target composition and the deposition rate during deposition at a total pressure of 14 Pa;

FIG. 8 is a graph showing the extinction coefficient of the samples in Experimental Example 3;

FIG. 9 is a graph showing the refractive index of the samples in Experimental Example 3;

FIG. 10 is a graph showing the transmittance characteristics of the sample under condition 4-5 in Experimental Example 4;

FIG. 11 is a graph showing the reflection characteristics of the sample under condition 4-5 in Experimental Example 4;

FIG. 12 is a graph showing the transmittance characteristics of the sample under condition 6-3 in Experimental Example 6; and

FIG. 13 is a graph showing the reflection characteristics of the sample under condition 6-3.

### DESCRIPTION OF THE PREFERRED EMBODIMENTS

A constitution of a method of forming a transparent optical film according to embodiments of the present invention will be described below. While the present invention will be described with reference to the embodiments shown in the drawings, it is to be understood that the invention is not limited the embodiments, and modifications may be made appropriately. Modified embodiments are covered within the scope of the invention as long as they have the operation and effect of the invention.

A method of forming a transparent optical film according to an embodiment of the present invention includes the step of forming an optical film that is transparent on a substrate by a reactive sputtering process using a Mg—Si metal target in an atmosphere into which a gas of a fluorine-containing compound is introduced and in which the total pressure is adjusted to 8 Pa or more.

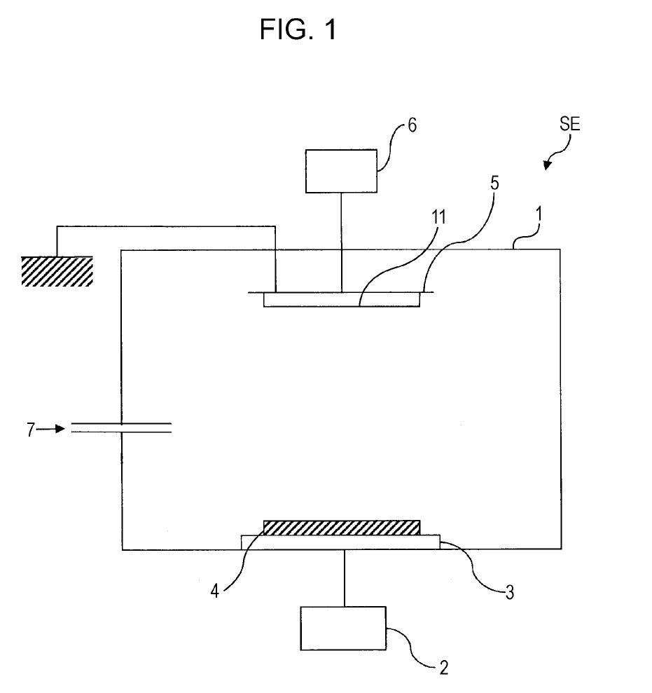

FIG. 1 shows an example of a structure of a reactive sputtering apparatus used in a method of forming a transparent optical film according to the embodiment of the present invention. As shown in FIG. 1, a reactive sputtering apparatus SE includes a substrate holder 5 for holding a substrate 11 on which a thin film is formed and a drive mechanism 6 rotating the substrate holder 5, the substrate holder 5 being provided on the upper portion inside a vacuum chamber 1. The vacuum chamber 1 is connected to a vacuum pump (not shown) for evacuating the vacuum chamber 1, and the vacuum inside the vacuum chamber 1 can be adjusted to a given value.

A sputtering electrode (cathode) 3 connected to a sputtering power source 2 and a plate-shaped Mg—Si metal target 4 disposed on the sputtering electrode 3 are arranged on the lower portion in the vacuum chamber 1 so as to face the substrate 11. The target 4 is a Mg—Si sintered target, and preferably, the Si content is higher than 0 mole percent and lower than or equal to 50 mole percent.

Furthermore, the sputtering power source 2 is a DC power source or an AC power source, and it is possible to perform AC sputtering (frequency: 20 to 90 kHz), DC sputtering, or DC-pulsed sputtering. The reactive sputtering process according to the embodiment of the present invention is not particularly limited as long as the film deposition is performed in a state where plasma is generated by applying an alternating current voltage or a direct current voltage between the substrate 11 and the target 4. For example, RF sputtering may be used. In such a case, preferably, plasma is confined using a magnetron system.

Furthermore, gas-introducing pipes are connected to the vacuum chamber 1. A gas 7, the flow rate of which is controlled by a mass flow controller (not shown), is introduced through one pipe into the vacuum chamber 1. The gas 7 is most preferably only a gas of a fluorine-containing compound. However, an inert gas or oxygen gas may be added to the gas of the fluorine-containing compound. In such a case, the flow ratio of the inert gas is set at 10% or less, and the flow ratio of the oxygen gas is set at 5% or less. Examples of the fluorine-containing compound, as the sputtering gas, include CF₄, C₂F₆, and CHF₃. Among these, CF₄ or C₂F₆ is preferable, and CF₄ is most preferable. The inert gas is, for example, at least one gas selected from Ar, Xe, Ne, and Kr.

Furthermore, by adjusting the total pressure during deposition to 8 Pa or more, and preferably 10 Pa or more, light absorption can be prevented in the optical film. A total pressure of 14±2 Pa is most preferable. The upper limit of the total pressure is 30 Pa or less.

Thereby, in the vacuum chamber 1, the Mg—Si metal target 4 is sputtered in an atmosphere into which a gas of a fluorine-containing compound is introduced and in which the total pressure is adjusted to 8 Pa or more.

In this embodiment, the transparent optical film is obtained by performing film deposition using the reactive sputtering apparatus SE according to the following procedure.

(S11) The substrate 11 is held by the substrate holder 5, and the Mg—Si metal target 4 is placed on a predetermined position of the sputtering electrode 3.

(S12) The vacuum chamber 1 is evacuated to a predetermined pressure or less, and the substrate holder 5 is rotated.

(S13) The gas 7 is introduced into the vacuum chamber 1. At this stage, the gas 7 is introduced while controlling the gas flow rate, and the desired total pressure is achieved.

(S14) Next, power is applied to the sputtering electrode 3. Thereby, plasma is generated above the Mg—Si metal target 4, and sputtering of the target 4 starts.

(S15) Once the sputtering condition is stabilized, film deposition on the substrate 11 held on the substrate holder 5 is started to obtain a transparent optical film with low refractive index and a predetermined thickness.

Thereby, it is possible to form, at a high deposition rate, an optical film in which no light absorption occurs in the visible region and which has a refractive index of 1.4 or less at a wavelength of 550 nm. It is considered that the reason for this is that when performing sputtering in an atmosphere of a gas of a fluorine atom-containing compound using a Mg—Si metal as the target, Si on the surface of the target is removed as a highly volatile substance, such as SiF₄, and unlike the case where a Mg metal target is used, the surface of the target is not covered with MgF₂, and a newly activated surface of the target is exposed. Thus, the deposition rate improves compared with the case where a Mg metal target is used. Furthermore, since Si contained in the target is removed as a highly volatile substance, such as SiF₄, Si is not contained in the resulting optical film.

Furthermore, as the substrate 11, a transparent glass substrate or a transparent resin substrate having a clean surface is used, the transparent resin substrate being made of a polymeric plastic film composed of, for example, polyethylene terephthalate (PET), polyethylene naphthalate (PEN), polycarbonate (PC), polyethersulfone (PES), or an amorphous polyolefin. Furthermore, when an Al₂O₃ thin film is provided on the surface of the substrate in advance, the adhesion of the transparent optical film according to the embodiment of the present invention can be ensured, which is preferable.

### EXAMPLES

With respect to methods of forming a transparent optical film according to embodiments of the present invention, the experimental results are shown below.

### Experimental Example 1

In the reactive sputtering apparatus SE shown in FIG. 1, a glass substrate (Corning 1737 glass manufactured by Corning Incorporated, USA) was used as the substrate 11 and set in the vacuum chamber 1. A Mg metal target was used as the target 4. Subsequently, the vacuum chamber 1 was evacuated to 5×10⁻⁴ Pa, and then CF₄, CHF₃, or C₂F₆ was introduced by itself as the gas 7 into the vacuum chamber 1. In an atmosphere in which the total pressure during deposition was adjusted to 2.4 Pa, three types of film deposition were performed by a reactive RF sputtering process, and thereby samples were obtained.

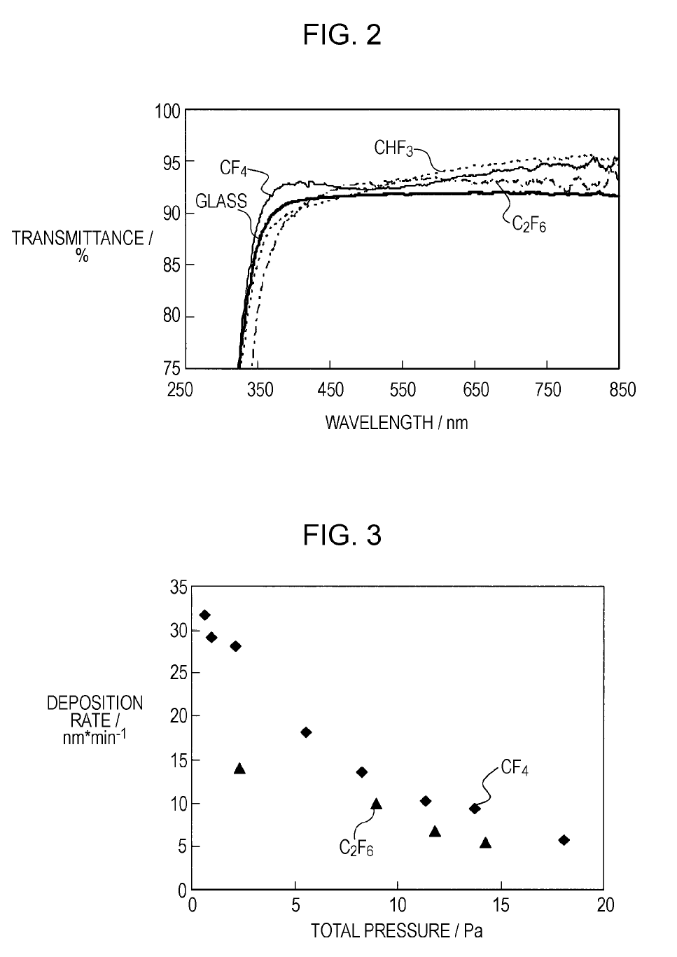

FIG. 2 shows the results of measurement of transmittance of the samples and the glass substrate. Even with the use of any of the gases, the transmittance exceeded that of the glass substrate at a wavelength of 500 nm or more, and a thin film having a lower refractive index than the glass substrate was formed.

Then, the adhesion of the thin films of the three samples was evaluated. When visually observed, the case where a continuous film was formed on the substrate was evaluated as good, and the case where a continuous film was not formed and detachment occurred was evaluated as defective. As a result, in the case where the gas species was CF₄ or C₂F₆, the sample was good, and in the case of CHF₃, the sample was defective. In the case of CHF₃, it is believed that, because of the increased number of dangling bonds due to H, the strength of the film was low, resulting in detachment.

In the reactive sputtering apparatus SE shown in FIG. 1, a glass substrate (Corning 1737 glass manufactured by Corning Incorporated, USA) was used as the substrate 11 and set in the vacuum chamber 1. A Mg metal target was used as the target 4. Subsequently, the vacuum chamber 1 was evacuated to 5×10⁻⁴ Pa, and then CF₄ or C₂F₆ was introduced by itself as the gas 7 into the vacuum chamber 1. In an atmosphere in which the total pressure during deposition was varied to 18 Pa, film deposition was performed by a reactive RF sputtering process, and the deposition rate was measured.

FIG. 3 shows the results thereof. As is evident from FIG. 3, the deposition rate was higher when CF₄ was used as the gas species. When the thin films formed at a total pressure of 14 Pa were measured by a spectroscopic ellipsometer, even if either one of CF₄ and C₂F₆ was used, the refractive index was 1.38, and the extinction coefficient was 0 at a wavelength of 550 nm. Thus, there was no difference in optical constants between the two. Consequently, although there is no difference in the optical quality of the film, CF₄ having a higher deposition rate is advantageous.

### Experimental Example 2

In the reactive sputtering apparatus SE shown in FIG. 1, a glass substrate (Corning 1737 glass manufactured by Corning Incorporated, USA) was used as the substrate 11 and set in the vacuum chamber 1. A Mg metal target was used as the target 4. Subsequently, the vacuum chamber 1 was evacuated to 5×10⁻⁴ Pa, and then CF₄ gas and Ar gas, as the gas 7, were introduced into the vacuum chamber 1. The experiments were carried out at three levels of the CF₄/Ar flow ratio, 100:0, 80:20, and 50:50. In an atmosphere in which the total pressure during deposition was adjusted to 14 Pa, film deposition was performed by a reactive AC sputtering process (frequency: 50 kHz) at an applied power of 1,000 W, and thereby samples were obtained.

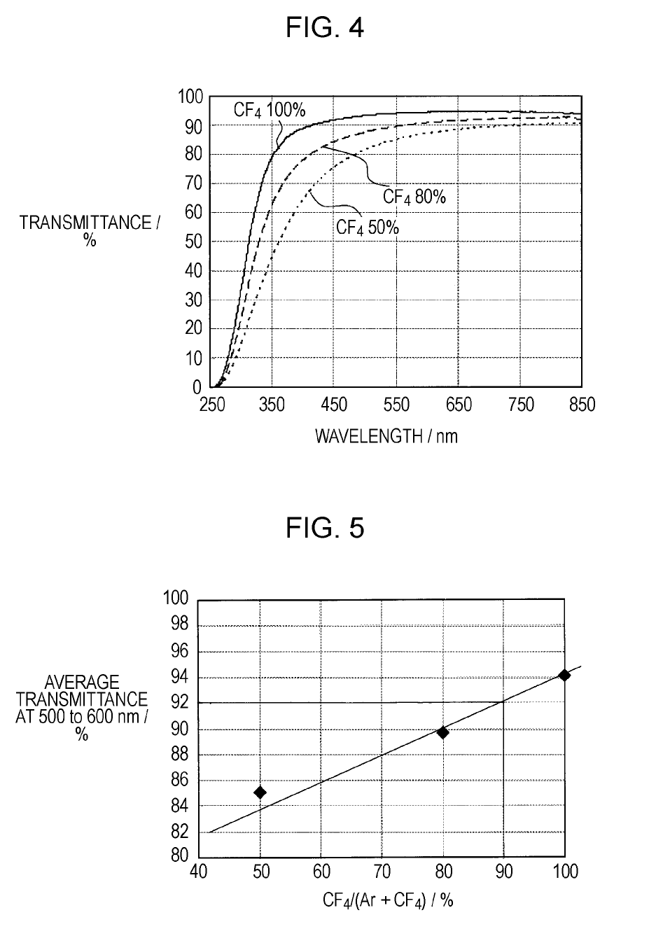

FIG. 4 shows the results of measurement of transmittance of the samples. As is obvious from FIG. 4, as the flow ratio of Ar gas increases, the transmittance tends to decrease.

On the basis of the results of measurement of transmittance shown in FIG. 4, the average transmittance at a wavelength of 500 to 600 nm was calculated for each CF₄/Ar flow ratio, and the results thereof are shown in FIG. 5. Since the transmittance allowable for the optical film is 92% or more, the Ar gas, as the inert gas, can be incorporated into the gas 7 at a flow ratio of 10% or less.

### Experimental Example 3

In the reactive sputtering apparatus SE shown in FIG. 1, a glass substrate (Corning 1737 glass manufactured by Corning Incorporated, USA) was used as the substrate 11 and set in the vacuum chamber 1. Each of three Mg—Si metal targets (Mg/Si compositional ratio of 9:1, 7:3, and 5:5, in terms of atomic ratio) was used as the target 4. Subsequently, the vacuum chamber 1 was evacuated to 5×10⁻⁴ Pa, and then CF₄ gas by itself was introduced as the gas 7 into the vacuum chamber 1. The total pressure during deposition was varied in a range of 0.3 to 18 Pa for each of the targets 4 having different Mg—Si compositional ratios, and without heating the substrate, film deposition was performed by a reactive AC sputtering process (frequency: 50 kHz) at an applied power of 1,000 W. For comparison, film deposition was performed under the same conditions except that a Mg metal target was used as the target 4.

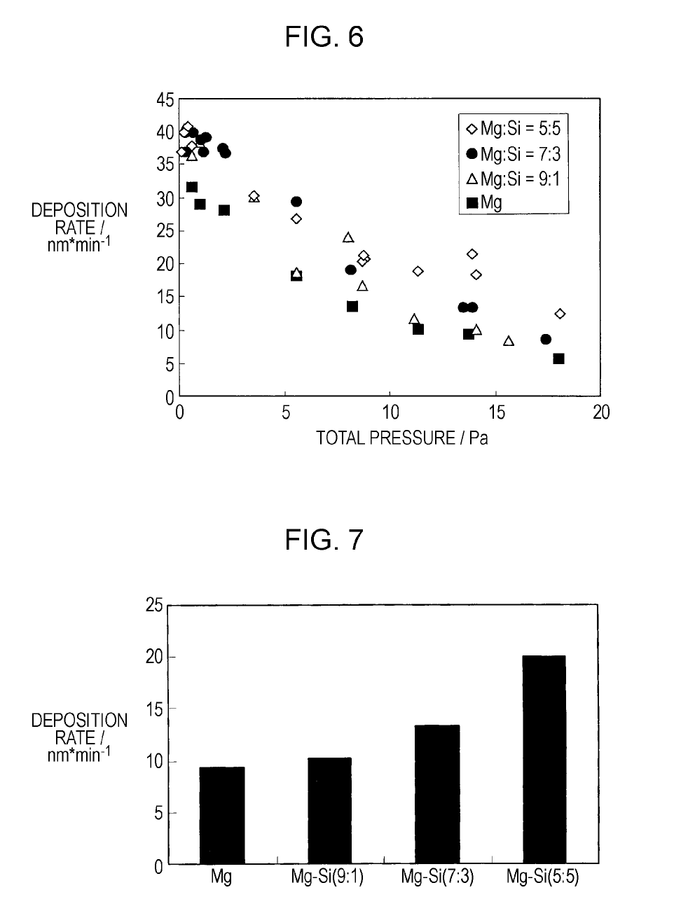

FIG. 6 is a graph showing the relationship between the total pressure and the deposition rate during deposition. As is evident from FIG. 6, at any pressure, the deposition rate in the case of use of the Mg—Si metal targets is higher than that in the case of use of the Mg metal target. Furthermore, as the Si content in the Mg/Si ratio increases, the deposition rate increases. FIG. 7 is a graph showing the deposition rates at a total pressure of 14 Pa shown in FIG. 6. The deposition rate for the Mg—Si target (Mg/Si=5:5) is 20 nm*min⁻¹, which is about twice the deposition rate of the Mg metal target.

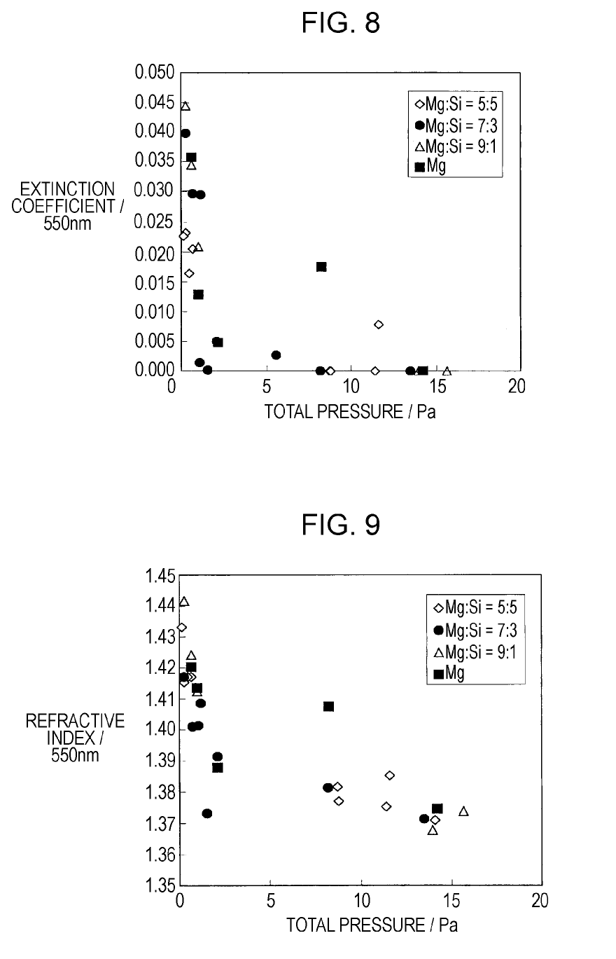

FIG. 8 shows the results of measurement of extinction coefficient of the samples in this experimental example at a wavelength of 550 nm. With respect to the sample of the Mg—Si metal target, the extinction coefficient is 0 at a total pressure of 8 Pa or more. Furthermore, as shown in FIG. 9, with respect to the samples of the Mg—Si metal targets, at a total pressure of 8 Pa or more, the refractive index at a wavelength of 550 nm tends to converge to 1.38.

That is, as is evident from the results, in the atmosphere into which a gas of a fluorine-containing compound (CF₄ gas) is introduced and in which the total pressure is adjusted to 8 Pa or more, by performing a reactive sputtering process using a Mg—Si metal target, a low-refractive-index optical film in which absorption is low in the visible region is formed at high rate. For example, in the reactive AC sputtering process (frequency: 50 kHz) using the Mg—Si metal target (Mg/Si compositional ratio=7:3) at an applied power of 1,000 W in the atmosphere into which CF₄ gas by itself was introduced and in which the total pressure was adjusted to 14 Pa, film deposition was performed at a deposition rate of 15 nm/min, and an optical film with a refractive index of 1.36 and an extinction coefficient of 0 (wavelength: 550 nm) was obtained.

Table 1 below shows the results of XPS analysis of the thin films with respect to the samples at a total pressure of 14 Pa in this experimental example. Table 1 also shows, for comparison, the results of XPS analysis of samples obtained at a total pressure of 1 Pa using the Mg—Si targets (compositional ratio: 10:0 and 7:3).

With respect to the transparent thin film formed at a total pressure of 14 Pa in which absorption does not occur, Si is not present in the film regardless of the use of any target. The reason for this is that Si is converted into a volatile substance, such as SiF₄, by CF₄ in the deposition atmosphere, and is not mixed into the film.

TABLE 1

| | | Total | | | | | | | | |
|---|---|---|---|---|---|---|---|---|---|---|
| | Target | pressure | | | | | | | | |
| | compositional | during | | Composition of optical film | | | | | | |
| | ratio | deposition | Film | (XPS analysis, at %) | | | | | | |
| Sample | (Mg:Si) | (Pa) | characteristics | C | O | F | Mg | Si | F/Mg | A/C* |
| 3-1 | 10:0 | 14 | Transparent | 3.16 | 3.02 | 65.0 | 28.4 | 0.33 | 2.29 | 1.00 |
| 3-2 | 9:1 | 14 | Transparent | 2.63 | 3.59 | 65.1 | 28.0 | 0.70 | 2.32 | 1.04 |
| 3-3 | 7:3 | 14 | Transparent | 3.65 | 2.23 | 66.5 | 26.9 | 0.67 | 2.48 | 1.00 |
| 3-4 | 5:5 | 14 | Transparent | 2.98 | 1.68 | 67.0 | 27.8 | 0.56 | 2.41 | 1.01 |
| 3-5 | 10:0 | 1 | Absorptive | 4.47 | 0.45 | 65.5 | 29.3 | 0.35 | 2.24 | 0.85 |
| 3-6 | 7:3 | 1 | Absorptive | 4.65 | 0.60 | 66.0 | 28.2 | 0.51 | 2.34 | 0.87 |

*Anion/cation

When a magnesium fluoride film or a transparent optical film according to an embodiment of the present invention was formed on a substrate composed of quartz, PET, or the like, adhesion with the substrate was low, resulting in detachment. Under these circumstances, the present inventors diligently conducted research on adhesion improvement and found that by disposing an Al₂O₃ thin film on the substrate, adhesion with a magnesium fluoride film or a transparent optical film according to the embodiment of the present invention can be ensured.

Particularly, (1) an Al₂O₃ film is deposited in an oxide form by a reactive sputtering process; (2) the Al₂O₃ film preferably has a thickness that completely covers the substrate, and more preferably has a thickness of 5 nm or more; and (3) when an Al₂O₃ film is deposited by reactive DC magnetron sputtering, film deposition is performed at an oxygen flow ratio of 50% or less.

The results of experiments on adhesion improvement will be described below.

### Experimental Example 4

An adhesion layer was formed on a quartz substrate by DC magnetron sputtering using an Al metal target. Specifically, first, the quartz substrate was set in a vacuum chamber, and the vacuum chamber was evacuated to 5×10⁻⁴ Pa. After presputtering was performed, Ar and O₂ were introduced into the chamber such that the total pressure was 0.6 Pa, and an adhesion layer composed of Al₂O₃ was formed by DC magnetron sputtering. At this stage, the oxygen flow ratio (O₂/(O₂+Ar)) was set at 20%, the applied power was set at 300 W, and Al₂O₃ thin films with a thickness of 0, 3, 5, 10, and 85 nm were deposited.

Next, a MgF₂ thin film was formed. In the reactive sputtering apparatus SE shown in FIG. 1, the substrate provided with the adhesion layer was set in the vacuum chamber 1, the vacuum chamber 1 was evacuated to 5×10⁻⁴ Pa, and then CF₄ gas was introduced into the vacuum chamber 1 such that the total pressure was 14 Pa. Subsequently, without heating the substrate, a MgF₂ thin film with a thickness of 90 nm was formed by a reactive AC sputtering process (frequency: 50 kHz) at an applied power of 1,000 W using a Mg metal target as the target 4. The resulting MgF₂ thin film had a refractive index of 1.38 and an extinction coefficient of 0 (at a wavelength of 550 nm). For comparison, using a Nb metal target, in place of the Al target used for forming the adhesion layer, Nb₂O₅ films with a thickness of 5, 10, and 20 nm were deposited at an oxygen flow ratio of 10%. Film deposition was performed under the same conditions in this example, except for the above.

In the samples thus obtained, the adhesion state of the thin film was evaluated. The evaluation was performed visually. The state in which the thin film adhered to the substrate as a continuous film without being separated from the substrate was evaluated as “no detachment observed” (symbol O), and the state in which the film had cracks and was separated from the substrate was evaluated as “detachment observed” (symbol x).

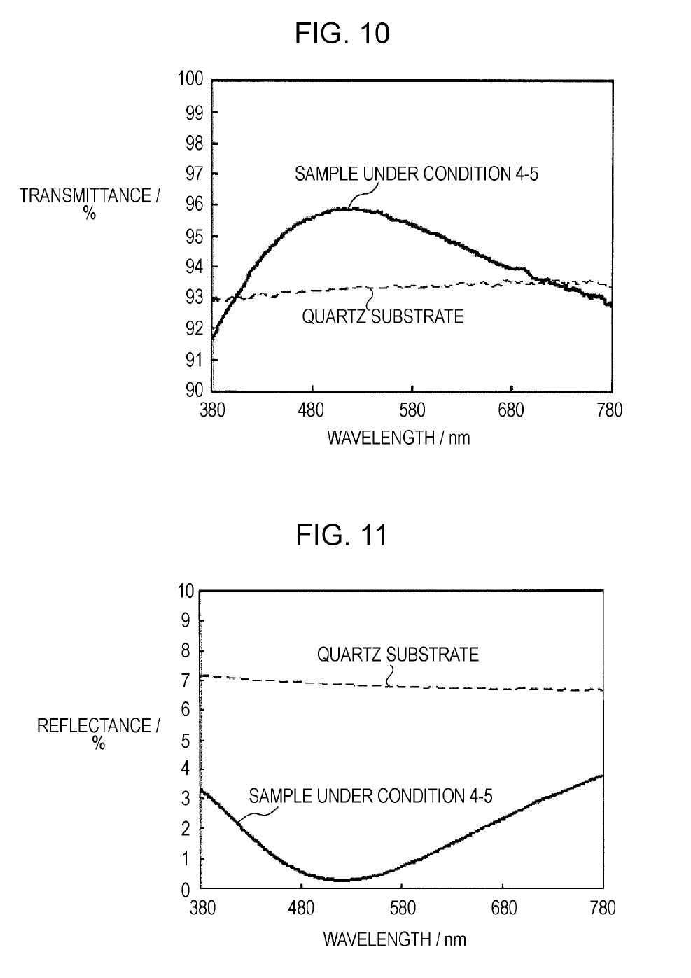

Table 2 shows the deposition conditions and the adhesion state of the film after deposition. The results show that when Al₂O₃ was used for the adhesion layer, no detachment was observed in the thin film. The transmittance of the thin film under condition 4-5 (Al₂O₃ thin film with a thickness of 85 nm) was measured and found to be improved compared with the transmittance of the quartz substrate in the visible wavelength region (FIG. 10). The reflectance of the thin film under condition 4-5 was measured and found to be lower than the reflectance of the quartz substrate in the entire wavelength region (380 to 780 nm) (FIG. 11). The results show that a good antireflection film was formed.

Furthermore, a transparent optical film according to an embodiment of the present invention was formed on an Al₂O₃ thin film using a Mg—Si metal target, instead of the MgF₂ thin film in this experimental example. As a result, a good adhesion state was observed as in this experimental example.

TABLE 2

| | | Experimental condition | | | | | | | |
|---|---|---|---|---|---|---|---|---|---|
| | | 4-1 | 4-2 | 4-3 | 4-4 | 4-5 | 4-6 | 4-7 | 4-8 |
| Adhesion layer | Material | None | Al₂O₃ | Al₂O₃ | Al₂O₃ | Al₂O₃ | Nb₂O₅ | Nb₂O₅ | Nb₂O₅ |
| | O₂ flow ratio (%) | None | 20 | 20 | 20 | 20 | 10 | 10 | 10 |
| | Thickness (nm) | 0 | 3 | 5 | 10 | 85 | 5 | 10 | 20 |
| MgF₂ | Thickness (nm) | 90 | 90 | 90 | 90 | 90 | 90 | 90 | 90 |

| | | | | | | | | |
|---|---|---|---|---|---|---|---|---|
| Evaluation of adhesion state | X | ◯ | ◯ | ◯ | ◯ | X | X | X |

### Experimental Example 5

An adhesion layer was formed on a PET film by DC magnetron sputtering using an Al metal target. Specifically, first, the PET film was set as a substrate in a vacuum chamber, and the vacuum chamber was evacuated to 5×10⁻⁴ Pa. After presputtering was performed, Ar and O₂ were introduced into the chamber such that the total pressure was 0.6 Pa, and an adhesion layer composed of Al₂O₃ was formed. At this stage, the oxygen flow ratio (O₂/(O₂+Ar)) was set at 20%, the applied power was set at 500 W, and Al₂O₃ films with a thickness of 0, 3, 5, 10, and 100 nm were deposited.

Next, a MgF₂ thin film was formed. In the reactive sputtering apparatus SE shown in FIG. 1, the substrate provided with the adhesion layer was set in the vacuum chamber 1, the vacuum chamber 1 was evacuated to 5×10⁻⁴ Pa, and then CF₄ gas was introduced into the vacuum chamber 1 such that the total pressure was 14 Pa. Subsequently, without heating the substrate, a MgF₂ thin film with a thickness of 80 nm was formed by a reactive AC sputtering process (frequency: 50 kHz) at an applied power of 1,000 W using a Mg metal target as the target 4.

With respect to the resulting samples, the adhesion state of the thin film was evaluated as in Experimental Example 4. The results thereof are shown in Table 3. As is evident from the results, the thickness of the Al₂O₃ thin film to be formed on the PET film is preferably 5 nm or more.

With respect to the samples with a thickness of 5, 10, and 100 nm (conditions 5-3 to 5-5) in which the evaluation results of adhesion state were good, in order to test adhesion, a thin film adhesion evaluation method was used in which the adhesion of a thin film was evaluated by pressing a diamond indenter onto the thin film under load. As a result, it was confirmed that the samples had substantially the same adhesion as that of an optical thin film (Nb₂O₅/SiOx/PET film) formed by a process in the related art.

The thin film adhesion evaluation method will be described below. That is, when a diamond indenter is perpendicularly pressed onto the thin film deposited on the substrate 11 while applying a maximum load, a phenomenon in which the thin film is cracked and detached from the substrate 11 occurs at a certain load point. In the method, the diamond indenter is pressed into the thin film while applying a maximum load, and indentation depth-load curve characteristics are determined. In the resulting indentation depth-load curve characteristics, the transition point from elastic deformation to plastic deformation of the thin film is defined as the detachment point, and thus the adhesion of the thin film to the substrate is quantitatively evaluated.

Furthermore, with respect to the samples with a thickness of 5, 10, and 100 nm (conditions 5-3 to 5-5), in order to determine environmental resistance, a test in which the samples were exposed in a thermostatic bath at 90° C. continuously for 100 hours and a boiling test in which the samples were placed in hot water at 95° C. for 5 minutes were carried out. In each of the tests, there were no substantial changes in optical constants before and after the test.

Furthermore, a transparent optical film according to an embodiment of the present invention was formed on an Al₂O₃ thin film (thickness: 5 nm or more) using a Mg—Si metal target, instead of the MgF₂ thin film in this experimental example. As a result, a good adhesion state was observed as in this experimental example.

TABLE 3

| | | Experimental condition | | | | |
|---|---|---|---|---|---|---|
| | | 5-1 | 5-2 | 5-3 | 5-4 | 5-5 |
| Adhesion | Material | None | Al₂O₃ | Al₂O₃ | Al₂O₃ | Al₂O₃ |
| layer | O₂ flow ratio | None | 20 | 20 | 20 | 20 |
| | (%) | | | | | |
| | Thickness (nm) | 0 | 3 | 5 | 10 | 100 |
| MgF₂ | Thickness (nm) | 80 | 80 | 80 | 80 | 80 |

| | | | | | |
|---|---|---|---|---|---|
| Evaluation of | X | ◯ | ◯ | ◯ | ◯ |
| adhesion state | | | | | |

### Experimental Example 6

An adhesion layer was formed on an acrylic hard coat-applied PET film by DC magnetron sputtering using an Al metal target. Specifically, first, the PET film was set in a vacuum chamber, and the vacuum chamber was evacuated to 5×10⁻⁴ Pa. After presputtering was performed, Ar and O₂ were introduced into the chamber such that the total pressure was 0.6 Pa, and an adhesion layer composed of Al₂O₃ was formed by DC magnetron sputtering. At this stage, the oxygen flow ratio (O₂/(O₂+Ar)) was set at 20%, the applied power was set at 700 W, and Al₂O₃ thin films with a thickness of 0, 3, 5, 10, and 100 nm were deposited. Furthermore, the oxygen flow ratio (O₂/(O₂+Ar)) was set at 10%, 50%, and 100%, the applied power was set at 700 W, and Al₂O₃ thin films with a thickness of 100 nm were deposited.

Next, a MgF₂ thin film was formed. In the reactive sputtering apparatus SE shown in FIG. 1, the substrate provided with the adhesion layer was set in the vacuum chamber 1, the vacuum chamber 1 was evacuated to 5×10⁻⁴ Pa, and then CF₄ gas was introduced into the vacuum chamber 1 such that the total pressure was 17 Pa. Subsequently, without heating the substrate, a MgF₂ thin film with a thickness of 100 nm was formed by a reactive AC sputtering process (frequency: 50 kHz) at an applied power of 1,000 W using a Mg metal target as the target 4.

With respect to the resulting samples, the adhesion state of the thin film was evaluated as in Experimental Example 4. The results thereof are shown in Table 4. As is evident from the results, the thickness of the Al₂O₃ thin film to be formed on the hard coat-applied PET film is preferably 5 nm or more (conditions 6-1 to 6-5). Furthermore, in the sample under condition 6-8 (oxygen flow ratio: 100%), detachment was observed. The reason for this is believed to be that since the adhesion layer was subjected to excessive stress, cracks were produced, resulting in detachment. For this reason, the oxygen flow ratio is preferably 50% or less.

TABLE 4

| | | Experimental condition | | | | | | | |
|---|---|---|---|---|---|---|---|---|---|
| | | 6-1 | 6-2 | 6-3 | 6-4 | 6-5 | 6-6 | 6-7 | 6-8 |
| Adhesion layer | Material | None | Al₂O₃ | Al₂O₃ | Al₂O₃ | Al₂O₃ | Al₂O₃ | Al₂O₃ | Al₂O₃ |
| | O₂ flow ratio (%) | None | 20 | 20 | 20 | 20 | 10 | 50 | 100 |
| | Thickness (nm) | 0 | 3 | 5 | 10 | 100 | 100 | 100 | 100 |
| MgF₂ | Thickness (nm) | 100 | 100 | 100 | 100 | 100 | 100 | 100 | 100 |

| | | | | | | | | |
|---|---|---|---|---|---|---|---|---|
| Evaluation of adhesion state | X | ◯ | ◯ | ◯ | ◯ | ◯ | ◯ | X |

With respect to the samples (conditions 6-3 to 6-7) in which the evaluation results of adhesion state were good, adhesion was measured using the thin film adhesion evaluation method. As a result, it was confirmed that the samples had substantially the same adhesion as that of an antireflection film (Nb₂O₅/SiOx/PET film) formed by a process in the related art. Furthermore, in order to determine environmental resistance, a test in which the samples were exposed in a thermostatic bath at 90° C. continuously for 100 hours and a boiling test in which the samples were placed in hot water at 95° C. for 5 minutes were carried out. In each of the tests, there were no substantial changes in optical constants before and after the test.

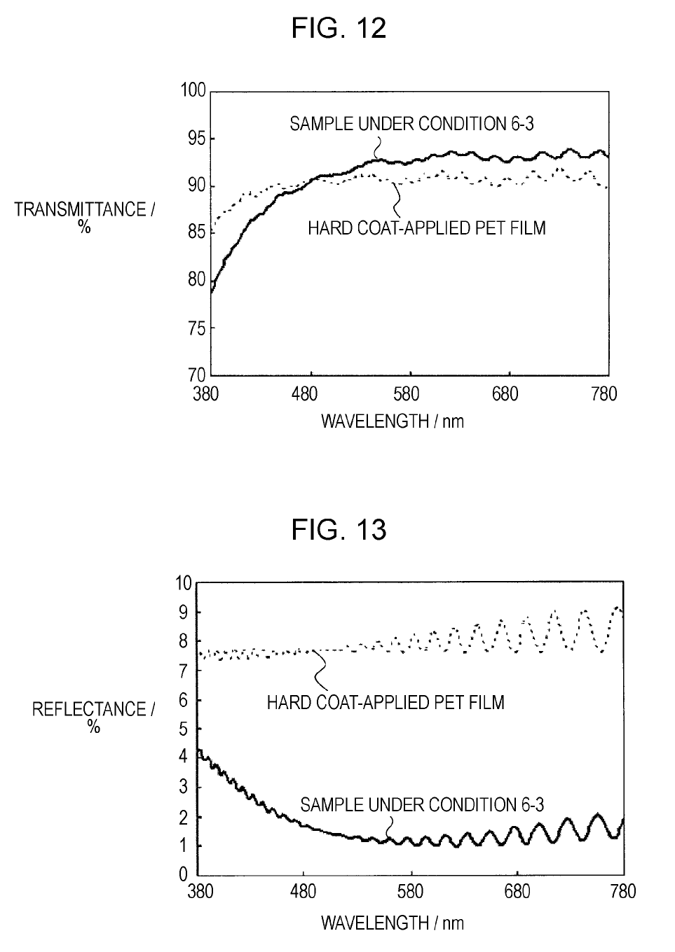

Furthermore, the transmittance of the thin film of the sample under condition 6-3 (Al₂O₃ thin film with a thickness of 5 nm) was measured and found to be improved compared with the transmittance of the hard coat-applied PET film in a visible wavelength range of 480 nm or more (FIG. 12). Furthermore, the reflectance of the sample under condition 6-3 was measured and found to be lower than the reflectance of the hard coat-applied PET film in the entire wavelength region (380 to 780 nm) (FIG. 13). The results show that a good antireflection film was formed.

Furthermore, a transparent optical film according to an embodiment of the present invention was formed on an Al₂O₃ thin film (thickness: 5 nm or more) using a Mg—Si metal target, instead of the MgF₂ thin film in this experimental example. As a result, a good adhesion state was observed as in this experimental example.

It should be understood by those skilled in the art that various modifications, combinations, sub-combinations and alterations may occur depending on design requirements and other factors insofar as they are within the scope of the appended claims or the equivalents thereof.

What is claimed is:

1. A method of forming a transparent optical film, comprising the step of:
forming an optical film that is transparent on a substrate by a reactive sputtering process using a Mg—Si metal target in an atmosphere into which a gas of a fluorine-containing compound is introduced and in which the total pressure is adjusted to 8 Pa or more.

2. The method according to claim 1, wherein the Si content in the Mg—Si metal target is 50 mole percent or less.

3. The method according to claim 1, wherein the fluorine-containing compound is CF₄ or C₂F₆.

4. The method according to claim 1, wherein, in the reactive sputtering process, an alternating current voltage or a direct current voltage is applied between the substrate and the target.

5. A transparent optical film formed on a substrate by a reactive sputtering process using a Mg—Si metal target in an atmosphere into which a gas of a fluorine-containing compound is introduced and in which the total pressure is adjusted to 8 Pa or more.
